(19) United States
(12) Patent Application Publication
(10) Pub. No.: US 2025/0348004 A1
(43) Pub. Date: Nov. 13, 2025

(54) PHOTORESIST STRIPPING COMPOSITION

(71) Applicant: KANTO KAGAKU KABUSHIKI KAISHA, Tokyo (JP)

(72) Inventors: Tsubasa ITO, Saitama (JP); Ryo SASAKI, Saitama (JP); Toshikazu SHIMIZU, Saitama (JP)

(21) Appl. No.: 18/728,981

(22) PCT Filed: Jan. 20, 2023
(86) PCT No.: PCT/JP2023/001641

§ 371 Date: Jul. 15, 2024

(30) Foreign Application Priority Data
Jan. 21, 2022 (JP) 2022-008175

(51) Int. Cl. G03F 7/42

(52) U.S. Cl. CPC G03F 7/425

(57) ABSTRACT

An object of the present invention is to provide a photoresist stripping composition which exhibits high stripping performance even for a cured resist, shows little decrease in stripping performance when water evaporates even with a composition containing a small amount of water, and can prevent corrosion of a substrate-forming metal, such as Cu, Al, or Si, that comes in contact with a liquid. The object was achieved by a photoresist stripping composition, the composition containing a quaternary ammonium hydroxide (A), a sugar alcohol (B), an amine (C), water (D), DMSO (E), and ethylene glycol (F), wherein a content of water (D) is 1.0 to 10 mass % with respect to a total mass of the composition.

### TECHNICAL FIELD

The present invention relates to a photoresist stripping composition.

### BACKGROUND ART

A semiconductor integrated circuit is produced by photolithography in which a metal wiring pattern of Cu or the like is formed on a silicon substrate or a glass substrate. The photolithography is performed by the steps of (1) applying a photoresist on a semiconductor substrate or a metal film, (2) transferring a wiring pattern by exposure and development, (3) forming and processing wiring by etching, plating, or the like, (4) peeling the photoresist, and the like.

Since the photoresist is an organic film, from the viewpoint of resist dissolution performance, a stripper that has a low water content or is nonaqueous is desirable. However, in the case of a stripper having a small water content, there arises a problem that water evaporates during a heat treatment and the balance of the stripping liquid composition is lost to deteriorate the stripping performance of the photoresist, and a stripping liquid containing even a small amount of water may cause damage to silicon or the like. Therefore, there has been a demand for a stripping liquid which shows little decrease in stripping performance when water evaporates and shows little damage to metal wiring and a substrate of Si or the like.

In addition, in order to efficiently strip a resist, it is necessary to fragment a polymer chain to improve the solubility and dispersibility in a liquid. Since fragmentation is achieved by hydrolysis of ester bonds in a polymer, it is desirable that the stripping liquid contains a strong base such as an amine or an ammonium salt hydroxide, but a stripping liquid containing a strong base in a water-containing composition may damage Si or Al. Therefore, there has been a demand for a stripper that is highly basic but shows little damage to Si, Al, or the like, and has a low water content, or is nonaqueous.

In addition, a stripper is used to remove an unnecessary photoresist film after an etching or plating process, but the photoresist is cured in the etching or plating process, and stripping often becomes difficult. Therefore, a stripper capable of removing a cured resist has been required.

Patent Literature 1 discloses a composition obtained by mixing THAH, EG, and DMSO, and a water-free composition obtained by mixing THAH, PG, and DMSO.

Patent Literature 2 describes a substantially moisture-free photoresist stripping composition useful for stripping a photoresist after an ion implantation step, such as a composition obtained by mixing THAH, EG, and DMSO.

Patent Literature 3 describes a photoresist stripper solution containing DMSO, TMAH, an alkanolamine, a corrosion preventive agent, and water.

### CITATION LIST

### Patent Literature

Patent Literature 1: JP 2006-317714 A
Patent Literature 2: JP 2013-500503 A
Patent Literature 3: JP 2019-113848 A

### SUMMARY OF INVENTION

### Technical Problem

However, the conventional photoresist stripper has problems such as insufficient stripping performance for an excessively cured photoresist, damage to metal wiring and a substrate of Si or the like, deterioration of stripping performance at the time of evaporation when water is contained, and high raw material and production cost.

In view of the above conventional problems, an object of the present invention is to provide a stripper which has high stripping performance even for a cured resist, shows little decrease in stripping performance when water evaporates even with a composition containing a small amount of water, and shows little damage to metal wiring and a substrate of Si or the like.

### Solution to Problem

As described above, a nonaqueous stripper is preferable for high resist dissolution performance, but since a quaternary ammonium salt frequently used in a stripper is usually produced and sold as an aqueous solution, it is necessary to remove water for a nonaqueous stripping liquid. As a means for this, use of an organic solvent solution of a quaternary ammonium salt is exemplified, but there is a disadvantage that the organic solvent solution of a quaternary ammonium salt is expensive as compared with an aqueous solution, and on the other hand, it takes time and effort and cost for production to evaporate water from an aqueous solution of a quaternary ammonium salt.

The present inventors have conducted studies in order to solve the above problems, and found that a photoresist stripping composition, the composition containing a quaternary ammonium hydroxide (A), a sugar alcohol (B), an amine (C), water (D), DMSO (E), and ethylene glycol (F), wherein a content of water (D) is 1.0 to 10 mass % with respect to a total mass of the composition, shows little decrease in stripping performance when water evaporates even with a composition containing a small amount of water, and shows little damage to metal wiring and a substrate of Si or the like, and have completed the present invention.

That is, the present invention relates to the following.
[1] A photoresist stripping composition, the composition containing a quaternary ammonium hydroxide (A), a sugar alcohol (B), an amine (C), water (D), DMSO (E), and ethylene glycol (F), wherein a content of water (D) is 1.0 to 10 mass % with respect to a total mass of the composition.
[2] The composition according to [1], wherein a content of (A) is 1.0 to 10 mass % with respect to the total mass of the composition, a content of (B) is 0.1 to 20 mass % with respect to the total mass of the composition, a content of (C) is 1.0 to 20 mass % with respect to the total mass of the composition, the content of (D) is 1.0 to 10 mass % with respect to the total mass of the composition, a content of (E) is 20 to 90 mass % with respect to the total mass of the composition, and a content of (F) is 1 to 10 mass % with respect to the total mass of the composition.
[3] The composition according to [1] or [2], wherein the amine (C) is at least one compound selected from monoethanolamine, diethanolamine, triethanolamine, N-methylaminoethanol, 2-(2-aminoethoxy) ethanol, 2-[2-(dimethylamino) ethoxy]ethanol, and diisopropanolamine, or a mixture thereof.
[4] The composition according to any one of [1] to [3], wherein the amine (C) is 2-(2-aminoethoxy) ethanol or 2-[2-(dimethylamino) ethoxy]ethanol.
[5] The composition according to any one of [1] to [4], wherein the composition does not contain a compound having a boiling point at 1 atm of 70° C. or lower.
[6] The composition according to any one of [1] to [5], wherein the quaternary ammonium hydroxide (A) is a compound represented by a general formula below or a mixture thereof, a content of which is 1 to 5%.
(R¹, R², R³, and R⁴ each independently represent an alkyl group having 1 to 3 carbon atoms or a hydroxyalkyl group)

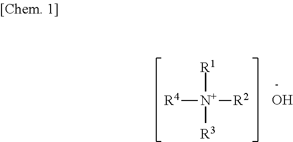

[7] The composition according to any one of [1] to [6], wherein the sugar alcohol (B) is at least one compound selected from sorbitol, xylitol, erythritol, mannitol, and glycerin, or a mixture thereof.
[8] A photoresist stripping method, including bringing a photoresist applied onto a substrate having metal wiring or a semiconductor substrate containing a photoresist residue into contact with the composition according to any one of [1] to [7] to remove the photoresist.

### Advantageous Effects of Invention

In the composition of the present invention, high stripping performance can be realized without damaging metal wiring and a substrate of Si or the like while the composition is strongly basic and contains water, and thus the composition can be applied to a highly difficult step requiring selectivity for a metal. In addition, since high stripping performance can be realized while corrosion of Si, Al, Cu, and the like are simultaneously prevented, the composition can also be applied to a more highly difficult step. Further, since there is no decrease in stripping performance due to evaporation of water, the composition can be used for a long time, and the number of liquid exchanges can be reduced. In addition, the production cost is lower than that of a conventional nonaqueous stripping liquid containing a strong base. Therefore, cost reduction and environmental load reduction can be achieved.

In particular, when EG was applied as an additive in addition to DMSO, the stripping performance was greatly improved as compared with, for example, the case of applying 1,3-PG or the like as an additive. Further, when EG was applied as an additive, the Si anticorrosive property was greatly improved as compared with, for example, the case of applying 1,3-PG or the like as an additive.

### BRIEF DESCRIPTION OF DRAWINGS

FIG. 1 shows the results of evaluating the molar electrical conductivity at 25° C. of a composition containing TMAH: 1%, H₂O: 3 to 50%, and a solvent (balance). The molar electrical conductivity is positively correlated with the ionization degree of TMAH. The higher the ionization degree of TMAH is, the more basic the solution is, and therefore, a trend can be obtained for the strength of basicity from the molar electrical conductivity.

FIG. 2 shows the results of evaluating the molar electrical conductivity at 25° C. of a composition containing TMAH: 1%, H₂O: 3 to 50%, and DMSO/a co-solvent (1:1 mol): balance. The molar electrical conductivity is positively correlated with the ionization degree of TMAH. The higher the ionization degree of TMAH is, the more basic the solution is, and therefore, a trend can be obtained for the strength of basicity from the molar electrical conductivity.

### DESCRIPTION OF EMBODIMENTS

Hereinafter, the present invention will be described in detail based on preferred embodiments of the present invention.

The photoresist stripping composition of the present invention is a photoresist stripping composition, and the composition is a composition containing a quaternary ammonium hydroxide (A), a sugar alcohol (B), an amine (C), water (D), DMSO (E), and ethylene glycol (F), wherein a content of water (D) is 1.0 to 10 mass % with respect to a total mass of the composition. The water content is low, the decrease in stripping performance when water evaporates is less, and the damage to metal wiring and Si is small.

In the present description, the numerical range “a to b” means “a or more and b or less”.

Hereinafter, each component contained in the composition of the present invention will be described.

### (A)

The quaternary ammonium hydroxide is a compound represented by a general formula below or a mixture thereof.

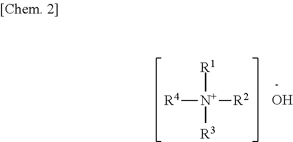

(R¹, R², R³, and R⁴ each independently represent an alkyl group or a hydroxyalkyl group.)

The quaternary ammonium hydroxide is a compound represented by a general formula below or a mixture thereof.

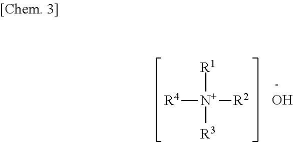

(R¹, R², R³, and R⁴ each independently represent an alkyl group having 1 to 3 carbon atoms or a hydroxyalkyl group.)

Examples of the quaternary ammonium hydroxide include tetramethylammonium hydroxide, tetraethylammonium hydroxide, tetrapropylammonium hydroxide, tetrabutylammonium hydroxide, ethyltrimethylammonium hydroxide, choline hydroxide, dimethyl bis(2-hydroxyethyl)ammonium hydroxide, and monomethyl tris(2-hydroxyethyl)ammonium hydroxide. The quaternary ammonium hydroxide is preferably one or more selected from the group consisting of tetramethylammonium hydroxide (TMAH), tetraethylammonium hydroxide, choline hydroxide, and ethyltrimethylammonium hydroxide from the viewpoint of solubility, cost, and the like. The quaternary ammonium hydroxide is more preferably tetramethylammonium hydroxide.

In an aspect, the quaternary ammonium hydroxide contains tetramethylammonium hydroxide. In an aspect, the quaternary ammonium hydroxide contains tetramethylammonium hydroxide in an amount of 1 mass % or more with respect to the total amount of the quaternary ammonium hydroxide.

The content of the quaternary ammonium hydroxide (A) is not particularly limited, but is preferably 1.0 to 10 mass % with respect to the total mass of the composition, more preferably 1.0% to 5.0%, and more preferably 1.0% to 3.0% from the viewpoint of preventing metal damage and reducing the water content.

The sugar alcohol (B) is a component that contributes as an Al corrosion preventive agent. The sugar alcohol is, for example, sorbitol, glycerin, or the like. The sugar alcohol is preferably at least one compound selected from the group consisting of sorbitol, xylitol, erythritol, mannitol, and glycerin, or a mixture thereof. The sugar alcohol may be a d-form, an 1-form, or a racemate.

The content of the sugar alcohol (B) is not particularly limited, but is preferably 0.1 to 20 mass %, and more preferably 0.1 to 10 mass % with respect to the total mass of the composition.

When the amine (C) is mixed, a resist can be decomposed by two types of active species of a hydroxy ion (OH⁻) and an amino group (—NH₂) of an ammonium salt, so that higher stripping performance can be obtained.

The content of the amine (C) is not particularly limited, but is preferably 1.0 to 20 mass %, and more preferably 1.0 to 15 mass % with respect to the total mass of the composition.

The amine is preferably an amino alcohol, and more preferably at least one compound selected from monoethanolamine, diethanolamine, triethanolamine, N-methylaminoethanol, 2-(2-aminoethoxy) ethanol, 2-[2-(dimethylamino) ethoxy]ethanol, and diisopropanolamine, or a mixture thereof. The amine is more preferably 2-(2-aminoethoxy) ethanol or 2-[2-(dimethylamino) ethoxy]ethanol from the viewpoint of high stripping performance and small damage to particularly Cu.

The content of water (D) is 1.0 to 10 mass % with respect to the total mass of the composition, and is preferably 1.0 to 6.0 mass % from the viewpoint of resist dissolution performance and the like.

Dimethyl sulfoxide (DMSO) (E) is a component that contributes as a solvent. The content of DMSO (E) is not particularly limited, but is preferably 20 to 90 mass %, more preferably 60 to 90 mass %, and still more preferably 60 to 85 mass % with respect to the total mass of the composition.

The present inventors have found that when DMSO is mixed with an alkyl ammonium hydroxide, the resulting solution is highly basic as compared with other commonly used solvents such as N-methyl-2-pyrrolidone (NMP) and diethylene glycol monoethyl ether (EDG), and high basicity can be realized with a low water concentration.

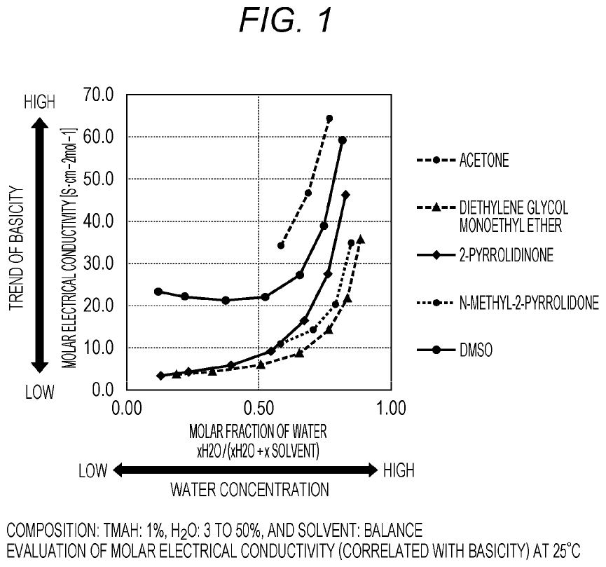

FIG. 1 is a graph showing the molar electrical conductivity of TMAH with respect to the water concentration of each solvent. The molar electrical conductivity is positively correlated with the ionization degree of TMAH. The higher the ionization degree of TMAH is, the more basic the solution is, and therefore, a trend can be obtained for the strength of basicity from the molar electrical conductivity. TMAH shows a high molar electrical conductivity at a low water concentration in DMSO as compared with other solvents. That is, TMAH is considered to have high basicity at a low water concentration in DMSO and is considered to be suitable for being combined with a small amount of water. Acetone also shows good results, but is not suitable as a stripping liquid because of its low flash point and low boiling point.

The composition of the present invention contains DMSO as a solvent, but DMSO and another solvent can also be used in combination. Examples of a preferred solvent include a glycol ether-based solvent and an amide-based solvent from the viewpoint of maintaining or improving the stripping performance.

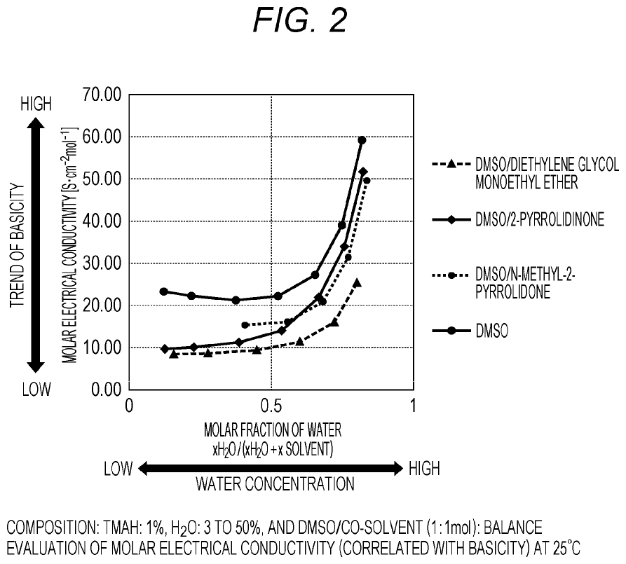

As shown in FIG. 1, when a glycol ether-based solvent or an amide-based solvent is used singly, the molar electrical conductivity of the TMAH solution is low, and the stripping performance is poor. FIG. 2 is a graph showing the molar electrical conductivity of a TMAH solution with respect to the water concentration when a solvent shown in FIG. 1 is mixed with DMSO. By mixing with DMSO, as compared with the case of a single glycol ether-based solvent and a single amide-based solvent (FIG. 1), the value of the molar electrical conductivity is increased in a range where the molar fraction of water is 0.5 or less. That is, it is considered that the basicity of the TMAH solution is enhanced at a low water concentration. Therefore, it is considered that a glycol ether-based or an amide-based solvent becomes an effective solvent as a stripping liquid by being mixed with DMSO.

Examples of the glycol ether-based solvent include diethylene glycol monoethyl ether, propylene glycol monomethyl ether, dipropylene glycol monomethyl ether, and ethylene glycol monoethyl ether. The glycol ether-based solvent is preferably diethylene glycol monoethyl ether, propylene glycol monomethyl ether, and the like.

Examples of the amide-based solvent include N-methyl-2-pyrrolidone, 1,3-dimethyl-2-imidazolidinone, 2-pyrrolidinone, and 1-(2-hydroxyethyl)-2-pyrrolidone. The amide-based solvent is preferably N-methyl-2-pyrrolidone, 1,3-dimethyl-2-imidazolidinone, and the like.

The composition of the present invention contains ethylene glycol (F). The content of ethylene glycol (F) is not particularly limited, but is preferably 1.0 to 10 mass %, and more preferably 5.0 to 10 mass % with respect to the total mass of the composition.

In an aspect, the composition of the present invention does not contain a compound having a boiling point at 1 atm of 70° C. or lower. Examples of the compound having a boiling point at 1 atm of 70° C. or lower include acetone and methanol.

The composition of the present invention may contain, for example, a surfactant or a Cu anticorrosive agent as an optional component.

As the surfactant, for example, a polyoxyethylene alkyl ether carboxylate, an alkylbenzene sulfonate, a polyoxyethylene alkyl ether phosphate, a polyoxyethylene alkyl ether, a halogenated tetraalkyl ammonium salt, an alkyl betaine, or the like can be used.

The surfactant may be contained, for example, in an amount of 0.01 to 3.0 mass % with respect to the total mass of the composition.

As the Cu anticorrosive agent, for example, imidazole, benzotriazole, adenine, or the like can be used.

The Cu anticorrosive agent may be contained, for example, in an amount of 0.01 to 3.0 mass % with respect to the total mass of the composition.

Even if the composition of the present invention contains 1.0 to 10 mass % of water, good stripping performance is maintained even after water evaporates. Although the reason is not necessarily clear, it is considered that ethylene glycol has an effect of swelling a resist, which is considered to be one of the roles of water. Ethylene glycol has a higher boiling point than water and is less likely to evaporate. Therefore, it is considered that good stripping performance is maintained as long as ethylene glycol remains even after water evaporates. If the addition amount of ethylene glycol is too large, the stripping performance before water evaporation is deteriorated, and if the addition amount of ethylene glycol is too small, the stripping performance after water evaporation is deteriorated. Therefore, it is desirable to add ethylene glycol at a mass % equivalent to the water concentration. In addition, it is considered that ethylene glycol not only contributes to maintenance of stripping performance, but also improves stripping performance, and further contributes to reduction of damage to metal wiring and Si.

The composition of the present invention is a composition for removing a photoresist applied onto a substrate having metal wiring.

In a Cu bumping process, after a photoresist is applied to a substrate, resist patterning is performed by exposure and development, resist openings are filled with Cu plating, and then the resist is stripped to form Cu bumps. The photoresist stripping composition of the present invention can be used when the photoresist is stripped by a wet process in the process.

In addition, in the Cu wiring forming process by etching, after a Cu film is formed on a substrate, a photoresist is applied, resist patterning is performed by exposure and development, and after Cu etching is performed, the photoresist remaining by being layered on the Cu wiring can be stripped by a wet process.

In an aspect, the present invention also relates to a photoresist stripping method including bringing a photoresist or a semiconductor substrate containing a photoresist residue into contact with the composition of the present invention to remove the photoresist or the photoresist residue.

The substrate containing a photoresist refers to, for example, a photoresist applied onto a substrate having metal wiring of Cu and Al or the like formed in the Cu bumping process or the wiring forming process, or the like.

The photoresist residue is a photoresist remaining after a photoresist removal treatment is performed before the photoresist residue is brought into contact with the composition of the present invention. Therefore, examples of the substrate containing a photoresist residue include a substrate on which a resist remains after the resist is roughly removed (ashing) with oxygen plasma.

In some aspects, the photoresist stripping method includes: (A) a step of providing a semiconductor substrate having a photoresist coating; (B) a step of exposing the semiconductor substrate having a photoresist coating to the stripping composition of the present invention to remove the photoresist; (C) a step of washing the semiconductor substrate, from which the photoresist has been removed, with ultrapure water, or 2-propanol and ultrapure water to remove the stripping liquid composition from the substrate; and (D) a step of drying.

The semiconductor substrate is usually formed of, but not particularly limited to, silicon, silicon oxide, silicon carbide, titanium oxide, aluminum oxide, gallium oxide, gallium nitride, indium phosphide, gallium arsenide, or the like.

Examples of a metal and a metal alloy in a wiring material, a contact material, an electrode material, or the like that forms the substrate include, but are not limited to, copper, aluminum, aluminum alloyed with copper, aluminum alloyed with silicon, titanium, cobalt, tungsten, ruthenium, nickel, chromium, molybdenum, palladium, gold, silver, indium tin oxide, and IGZO.

In some aspects, the stripping composition can be used at about 25 to about 90° C. In some aspects, the stripping composition can be used in a temperature range from about 40° C. to about 80° C. In some aspects, the stripping composition can be used in a temperature range from about 50° C. to about 70° C.

The stripping time can vary depending on the type of the resist, thermal history, and the like. When stripping is performed in a batch treatment, a suitable time range is usually about 5 to 30 minutes.

### Examples

The present invention will be described together with the following examples and comparative examples, and the contents of the invention will be described in more detail, but the present invention is not limited to these examples.

The following were used as solvents, reagents, and the like.
Dimethyl sulfoxide (DMSO); manufactured by Kanto Chemical Co., Inc.
Monoethanolamine (MEA); manufactured by Kanto Chemical Co., Inc.
Tetramethylammonium hydroxide (TMAH); manufactured by Kanto Chemical Co., Inc.
D-sorbitol (D-Sor); manufactured by Kanto Chemical Co., Inc.
Ethylene glycol (EG); manufactured by Kanto Chemical Co., Inc.
Diethylene glycol monoethyl ether (EDG); manufactured by Kanto Chemical Co., Inc.
1,3-Dimethyl-2-imidazolidinone (DMI); manufactured by Kanto Chemical Co., Inc.
N-methyl-2-pyrrolidone (NMP); manufactured by Kanto Chemical Co., Inc.
Diethanolamine (DEA); manufactured by Kanto Chemical Co., Inc.
Triethanolamine (TEA); manufactured by Kanto Chemical Co., Inc.
N-methylmonoethanolamine (MeMEA); manufactured by Kanto Chemical Co., Inc.
2-(2-Aminoethoxy) ethanol (AEE); manufactured by Tokyo Chemical Industry Co., Ltd.
Diisopropanolamine (DIPA); manufactured by Tokyo Chemical Industry Co., Ltd.
Tetrahydrofurfuryl alcohol (THFA); manufactured by Kanto Chemical Co., Inc.
Tetraethylammonium hydroxide (TEAH); manufactured by Tokyo Chemical Industry Co., Ltd.
Tetrabutylammonium hydroxide (TBAH); manufactured by Tokyo Chemical Industry Co., Ltd.
1,2-Propanediol (1,2-PG); manufactured by Kanto Chemical Co., Inc.
1,3-Propanediol (1,3-PG); manufactured by Tokyo Chemical Industry Co., Ltd.
2-[2-(Dimethylamino) ethoxy]ethanol (dimethyl AEE); manufactured by Tokyo Chemical Industry Co., Ltd.

The preparation of a stripping composition and evaluation thereof were performed as follows.

### [Preparation of Stripping Composition]

A stripping composition was prepared by blending each component at a concentration shown in the following table.

### [Evaluation of Stripping Performance]

For the evaluation of stripping performance, a Si substrate, in which an alkali development negative resist was applied onto a copper sputtered film and patterned, and then copper bumps were formed by copper plating, was used. The stripping treatment was performed by immersion in the stripping liquid at 60° C. for 10 minutes. After completion of the immersion in the stripping liquid, an overflow rinse with water was performed for 1 minute, and the substrate was dried by blowing nitrogen. The stripping performance was evaluated by observing the dried substrate with an optical microscope.

The evaluation of stripping performance is in three stages, and O, Δ, and X represent the following meanings.
O: Stripping performance is good (there is no resist residue).
Δ: Stripping performance is generally good (there is a slight resist residue).
X: Stripping performance is insufficient (there is a resist residue).

### [Evaluation of AlCu Damage]

For the evaluation of AlCu damage, a Si substrate, on which an AlCu sputtered film of 100 nm was formed, was used. The substrate was immersed in the stripping liquid at 60° C. for 10 minutes, and then an overflow rinse with water was performed for 1 minute, and the substrate was dried by blowing nitrogen. The AlCu film thickness of the dried substrate was analyzed using a wavelength dispersive fluorescent X-ray analyzer, and the etching rate (nm/min) was calculated.

The evaluation of AlCu damage is in two stages, and O and X represent the following meanings.
O: AlCu etching rate≤0.5 nm/min
X: AlCu etching rate>0.5 nm/min

TABLE 1

| | Component (mass %) | | | | | | | |
|---|---|---|---|---|---|---|---|---|
| | | | Quaternary | | Sugar | | | Al |
| | Solvent | Amine | ammonium | Water | alcohol | Additive | Stripping | anticorrosive |
| | (E) | (C) | hydroxide (A) | (D) | (B) | (F) | performance | property |
| Example 1 | DMSO (81.6) | MEA (2) | TMAH (1.85) | H2O (5.55) | D-Sor (3) | EG (6) | ◯ | ◯ |
| Example 2 | DMSO (20) + EDG (61.6) | MEA (2) | TMAH (1.85) | H2O (5.55) | D-Sor (3) | EG (6) | ◯ | ◯ |
| Example 3 | DMSO (20) + DMI (81.6) | MEA (2) | TMAH (1.85) | H2O (5.55) | D-Sor (3) | EG (6) | ◯ | ◯ |
| Example 4 | DMSO (20) + NMP (61.6) | MEA (2) | TMAH (1.85) | H2O (5.55) | D-Sor (3) | EG (6) | Δ | ◯ |
| Example 5 | DMSO (80.16) | DEA (3.44) | TMAH (1.85) | H2O (5.55) | D-Sor (3) | EG (6) | Δ | ◯ |
| Example 6 | DMSO (78.71) | TEA (4.89) | TMAH (1.85) | H2O (5.55) | D-Sor (3) | EG (6) | Δ | ◯ |
| Example 7 | DMSO (81.14) | MeMEA (2.46) | TMAH (1.65) | H2O (5.55) | D Sor (3) | EG (6) | Δ | ◯ |
| Example 8 | DMSO (80.7) | AEE (2.5) | TMAH (1.95) | H2O (5.85) | D-Sor (3) | EG (6) | ◯ | ◯ |
| Example 9 | DMSO (79,24) | DIPA (4.36) | TMAH (1.85) | H2O (5.55) | D-Sor (3) | EG (6) | Δ | ◯ |
| Example 10 | DMSO (80.46) | MEA (2) | TEAH (2.99) | H2O (5.55) | D-Sor (3) | EG (6) | Δ | ◯ |
| Example 11 | DMSO (75.82) | MEA (2) | TBAH (5.27) | H2O (7.91) | D-Sor (3) | EG (6) | ◯ | ◯ |
| Example 12 | DMSO (80.99) | MEA (2) | Choline | H2O (5.55) | D-Sor (3) | EG (6) | Δ | ◯ |
| | | | (2.46) | | | | | |
| Example 13 | DMSO (81.6) | MEA (2) | TMAH (1.85) | H2O (5.55) | Xylitol (3) | EG (6) | ◯ | ◯ |
| Example 14 | DMSO (81.6) | MEA (2) | TMAH (1.85) | H2O (5.55) | Mannitol (3) | EG (6) | Δ | ◯ |
| Example 15 | DMSO (81.6) | MEA (2) | TMAH (1.85) | H2O (5.55) | meso- | EG (6) | Δ | ◯ |
| | | | | | Erythritol (3) | | | |
| Example 16 | DMSO (81.6) | MEA (2) | TMAH (1.85) | H2O (5 55) | Glycerin (3) | EG (6) | Δ | ◯ |
| Comparative | DMSO (87.6) | MEA (2) | TMAH (1.85) | H2O (5.55) | DASor (3) | — | X | ◯ |
| Example 1 | | | | | | | | |
| Comparative | EDG (81.6) | MEA (2) | TMAH (1.85) | H2O (5.55) | Glycerin (3) | EG (6) | X | — |
| Example 2 | | | | | | | | |
| Comparative | DMSO (81.6) | MEA (2) | TMAH (1.85) | H2O (5.55) | D-Sor (3) | 1,3-PG (6) | X | ◯ |
| Example 3 | | | | | | | | |

The addition of EG which is an additive improved the stripping performance (Example 1 and Comparative Example 1).

When EDG was used alone as a solvent, the stripping performance was poor (Comparative Example 2), but when EDG was mixed with DMSO, good stripping performance was exhibited (Example 2). In addition, the solvents with which good stripping performance was exhibited when mixed with DMSO were DMI and NMP which are amide-based solvents (Examples 2, 3, and 4).

As the amine, in the case of MEA, DEA, TEA, MeMEA, AEE, and DIPA, relatively good stripping performance was exhibited. Among them, in the case of AEE, almost the same excellent stripping performance was exhibited as in the case of MEA (Examples 1, 5, 6, 7, 8, and 9).

As the ammonium salt, also in the case of TEAH, TBAH, and choline other than TMAH, good stripping performance was exhibited (Examples 10, 11, and 12).

As the Al anticorrosive agent other than D-sorbitol, xylitol, D-mannitol, meso-erythritol, glycerin, and the like were effective (Examples 13, 14, 15, and 16).

When EG was applied as an additive (Example 1), the stripping performance was greatly improved as compared with a case where 1,3-PG was applied (Comparative Example 3).

### [Evaluation of Cu Damage]

For the evaluation of Cu damage, a Si substrate, on which a Cu sputtered film of 100 nm was formed, was used. The substrate was immersed in the stripping liquid at 60° C. for 10 minutes, and then an overflow rinse with water was performed for 1 minute, and the substrate was dried by blowing nitrogen. The copper film thickness of the dried substrate was analyzed using a wavelength dispersive fluorescent X-ray analyzer, and the etching rate (nm/min) was calculated.

### (Evaluation)

O: Cu etching rate≤0.5 nm/min
Δ: 0.5 nm/min<Cu etching rate≤3.0 nm/min
X: Cu etching rate>3.0 nm/min

TABLE 2

| | Component (mass %) | | | | | | | |
|---|---|---|---|---|---|---|---|---|
| | | | Quaternary | | Sugar | | | Cu |
| | Solvent | Amine | ammonium | Water | alcohol | Addition | Stripping | anticorrosive |
| | (E) | (C) | hydroxide (A) | (D) | (B) | (F) | performance | property |
| Example 17 | DMSO (80.7) | AEE (2.5) | TMAH (1.95) | H2O (5.85) | D-Sor (3) | EG (6) | ◯ | ◯ |
| Example 18 | DMSO (80) | Dimethyl | TMAH (1.95) | H2O (5.85) | D-Sor (3) | EG (6) | ◯ | ◯ |
| | | AEE (3.2) | | | | | | |
| Example 19 | DMSO (81.6) | MEA (2) | TMAH (1.85) | H2O (5.55) | D-Sor (3) | EG (6) | ◯ | Δ |
| Example 20 | DMSO (80.16) | DEA (3.44) | TMAH (1.85) | H2O (5.55) | D-Sor (3) | EG (6) | Δ | ◯ |
| Example 21 | DMSO (78.71) | TEA (4.89) | TMAH (1.85) | H2O (5.55) | D-Sor (3) | EG (6) | Δ | ◯ |
| Comparative | DMSO (83.6) | — | TMAH (1.85) | H2O (5.55) | D-Sor (3) | EG (6) | X | ◯ |
| Example 4 | | | | | | | | |
| Comparative | DMSO (70) | MEA (30) | — | | | | X | X |
| Example 5 | | | | | | | | |

When AEE or dimethyl AEE was used, Cu damage could be prevented while stripping performance was maintained (Examples 17 and 18). When MEA was used, stripping performance was good, and Cu damage prevention was generally good (Example 19). Cu damage could be prevented even with a composition to which DEA or TEA was added other than AEE and dimethyl AEE, and the stripping performance was also generally good (Examples 20 and 21). On the other hand, in the composition in which no amine was added, Cu damage was small, but the stripping performance was insufficient (Comparative Example 4).

### [Evaluation of Si Damage]

A Si substrate was used for evaluation of Si damage. The substrate was immersed in a 0.5% HF aqueous solution at room temperature for 2 minutes, and then an overflow rinse with water was performed for 1 minute, and the substrate was dried by blowing nitrogen. The mass of the dried substrate was measured with a precision balance and defined as the mass before the treatment. Thereafter, the substrate was immersed in the stripping liquid at 60° C. for 1 hour, and then an overflow rinse with water was performed for 1 minute, and the substrate was dried by blowing nitrogen. The mass of the dried substrate was measured with a precision balance and defined as the mass after the treatment. The etching rate (nm/min) was calculated from the mass change before and after the treatment.

### (Evaluation)

O: Si etching rate≤1.0 nm/min
Δ: 1.0 nm/min<Si etching rate≤3 nm/min
X: Si etching rate>3.0 nm/min

TABLE 3

| | Component (mass %) | | | | | | | |
|---|---|---|---|---|---|---|---|---|
| | | | Quaternary | | Sugar | | | Si |
| | Solvent | Amine | ammonium | Water | alcohol | Additive | Stripping | anticorrosive |
| | (E) | (C) | hydroxide (A) | (D) | (B) | (F) | Performance | property |
| Example 22 | DMSO (81.6) | MEA (2) | TMAH (1.85) | H2O (5.55) | D-Sor (3) | EG (6) | ◯ | ◯ |
| Example 23 | DMSO (80.7) | AEE (2.5) | TMAH (1.95) | H2O (5.85) | D-Sor (3) | EG (6) | ◯ | ◯ |
| Comparative | DMSO (87.8) | MEA (2) | TMAH (1.85) | H2O (5.55) | D-Sor (3) | — | X | X |
| Example 6 | | | | | | | | |
| Comparative | DMSO (81.6) | MEA (2) | TMAH (1.85) | H2O (5.55) | D-Sor (3) | 1.3-PG (6) | X | Δ |
| Example 7 | | | | | | | | |

The addition of EG provided a high Si anticorrosive property (Examples 22 and 23, and Comparative Example 6). It was found that EG can provide excellent Si anticorrosion as compared with 1,3-PG (Example 22 and Comparative Example 7).

[Evaluation of Stripping Performance when Water Evaporated]

The stripping performance was evaluated in the same manner using a stripping liquid obtained by leaving the prepared stripping liquid open at 90° C. for 30 minutes to 1 hour to evaporate 3 to 4% of water.

TABLE 4

| | Component (mass %) | | | | | | Stripping | Stripping |
|---|---|---|---|---|---|---|---|---|
| | | | Quaternary | | Sugar | | performance | performance |
| | Solvent | Amine | ammonium | Water | alcohol | Additive | before water | after water |
| | (E) | (C) | hydroxide (A) | (D) | (B) | (F) | evaporation | evaporation |
| Example 24 | DMSO (81.5) | MEA (2) | TMAH (1.85) | H2O (5.55) | D-Sor (3) | EG (6) | ◯ | ◯ |
| Comparative | DMSO (88) | MEA (2) | TMAH (2) | H2O (6) | D-Sor (2) | — | ◯ | X |
| Example 8 | | | | | | | | |
| Comparative | DMSO (81.0) | MEA (2) | TMAH (1.85) | H2O (5.55) | D-Sor (3) | 1,3-PG (6) | X | Δ |
| Example 9 | | | | | | | | |

It was verified that the composition to which EG was added (Example 24) could prevent a decrease in stripping performance after evaporation of water as compared with the composition to which EG was not added (Comparative Example 8). In addition, it was found that when EG was added, the stripping performance was excellent as compared with a case where 1,3-PG was added (Comparative Example 9).

1. A photoresist stripping composition,
the composition comprising a quaternary ammonium hydroxide (A), a sugar alcohol (B), an amine (C), water (D), DMSO (E), and ethylene glycol (F), wherein
a content of water (D) is 1.0 to 10 mass % with respect to a total mass of the composition.

2. The composition according to claim 1, wherein a content of (A) is 1.0 to 10 mass % with respect to the total mass of the composition, a content of (B) is 0.1 to 20 mass % with respect to the total mass of the composition, a content of (C) is 1.0 to 20 mass % with respect to the total mass of the composition, the content of (D) is 1.0 to 10 mass % with respect to the total mass of the composition, a content of (E) is 20 to 90 mass % with respect to the total mass of the composition, and a content of (F) is 1 to 10 mass % with respect to the total mass of the composition.

3. The composition according to claim 1 or 2, wherein the amine (C) is at least one compound selected from monoethanolamine, diethanolamine, triethanolamine, N-methylaminoethanol, 2-(2-aminoethoxy) ethanol, 2-[2-(dimethylamino) ethoxy]ethanol, and diisopropanolamine, or a mixture thereof.

4. The composition according to any one of claims 1 to 3, wherein the amine (C) is 2-(2-aminoethoxy) ethanol or 2-[2-(dimethylamino) ethoxy]ethanol.

5. The composition according to any one of claims 1 to 4, wherein the composition does not contain a compound having a boiling point at 1 atm of 70° C. or lower.

6. The composition according to any one of claims 1 to 5, wherein the quaternary ammonium hydroxide (A) is a compound represented by a general formula below or a mixture thereof, a content of which is 1 to 5%: 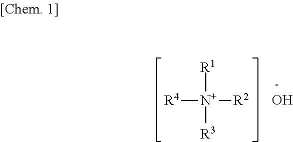
wherein R¹, R², R³, and R⁴ each independently represent an alkyl group having 1 to 3 carbon atoms or a hydroxyalkyl group.

7. The composition according to any one of claims 1 to 6, wherein the sugar alcohol (B) is at least one compound selected from sorbitol, xylitol, erythritol, mannitol, and glycerin, or a mixture thereof.

8. A photoresist stripping method, comprising bringing a photoresist applied onto a substrate having metal wiring or a semiconductor substrate containing a photoresist residue into contact with the composition according to any one of claims 1 to 7 to remove the photoresist.
